(19) United States
(12) Patent Application Publication
(10) Pub. No.: US 2010/0200065 A1
(43) Pub. Date: Aug. 12, 2010

(54) Photovoltaic Cell and Fabrication Method Thereof

(76) Inventor: Kyu Hyun Choi, (US)

Correspondence Address: ORRICK, HERRINGTON & SUTCLIFFE, LLP;IP PROSECUTION DEPARTMENT, 4 PARK PLAZA, SUITE 1600, IRVINE, CA, 92614-2558, US

(21) Appl. No.: 12/704,967

(22) Filed: Feb. 12, 2010

Related U.S. Application Data
(60) Provisional application No. 61/207,359, filed on Feb. 12, 2009.
(60) Provisional application No. 61/209,003, filed on Mar. 3, 2009.

(51) Int. Cl. H01L 31/00; H01L 31/18

(52) U.S. Cl. 136/261; 438/98; 257/E21.294

(57) ABSTRACT

The present structure and method for fabrication thereof provides a photovoltaic cell structure for converting light energy into electrical energy. According to one embodiment, a pillared photovoltaic cell structure comprises an array of pillars that are situated closely to each other to take advantage of both the wave-like properties and the particle-like properties of light to enhance the energy conversion efficiency of the photovoltaic cell. According to one embodiment, a pillared photovoltaic cell structure incorporating self-aligned P/P+ junctions enable holes generated near the top surface of the cell structure to be captured by the self-aligned P/P+ junctions.

The present application claims the benefit of and priority to U.S. Provisional Patent Application No. 61/207,359 filed on Feb. 12, 2009, entitled “Method of Improving Solar Cell Efficiency in Silicon Crystal,” and to U.S. Provisional Patent Application No. 61/209,003 filed on Mar. 3, 2009, entitled “Method of Improving Solar Cell Efficiency in Silicon Crystal using Pillar Structures.” U.S. Provisional Patent Applications 61/207,359 and 61/209,003 are herein incorporated by reference.

### FIELD

The present apparatus and method relate to photovoltaic cells, and particularly, to improving their efficiency in capturing and converting light energy to electrical energy.

### BACKGROUND

The technology to convert light energy into electrical energy is known as photovoltaics (PV). Today, photovoltaic cells are commonly used in consumer systems such as calculators, watches, electrical chargers for portable devices, and even automobiles. In a large-scale setting, numerous photovoltaic cells can connected be together as an array to collectively convert solar energy into electrical energy. A solar array of sufficient size can generate enough electrical energy to sustain a home or even an office building. Unlike conventional energy derived from resources such as coal, oil, and uranium, solar energy is renewable and can be converted into electrical energy without producing by-products that are harmful to the environment. This makes harnessing solar energy very desirable.

Although there are different constructions of photovoltaic cells, such as dye-sensitive cells and thin-film cells, semiconductor-based cells remain the most common because of their more efficient performance. A semiconductor-based photovoltaic cell is generally made on a monocrystalline or polycrystalline semiconductor substrate, such as silicon, gallium arsenide (GaAs), cadmium telluride (CdTe) or copper indium selenide (CuInSe²). The use of amorphous silicon is also possible. Near the top surface of the substrate, a P-N junction may be created through a doping process.

### SUMMARY

A photovoltaic cell structure is disclosed. According to one embodiment, a photovoltaic cell structure comprises a semiconductor substrate; a plurality of pillars formed from the semiconductor substrate, each one of the plurality of pillars having one or more lateral surfaces; and a P-N junction formed underneath the one or more lateral surfaces of the plurality of pillars.

### BRIEF DESCRIPTION OF THE DRAWINGS

The accompanying drawings, which are included as part of the present specification, illustrate the presently preferred embodiment and together with the general description given above and the detailed description of the preferred embodiment given below serve to explain and teach the principles described herein.

FIG. 1A illustrates a lateral cross-sectional view of a prior art planar solar cell structure;

FIG. 1B illustrates a lateral cross-sectional view of a prior art solar cell structure with a textured surface;

FIG. 1C illustrates a lateral cross-sectional view of a prior art solar cell structure with trenches;

FIG. 2 illustrates a lateral cross-sectional view of an exemplary pillared solar cell structure, according to one embodiment;

FIG. 3A illustrates a three-dimensional view of an exemplary pillared solar cell structure with rectangular pillars, according to one embodiment;

FIG. 3B illustrates a top view of an exemplary pillared solar cell structure, according to one embodiment;

FIG. 3C illustrates a top view of an exemplary pillared solar cell structure with a staggered alignment, according to another embodiment;

FIG. 3D illustrates a three-dimensional view of an exemplary pillared solar cell structure with cylindrical pillars, according to one embodiment;

FIG. 3E illustrates a top view of an exemplary pillared solar cell structure with cylindrical pillars and a staggered alignment, according to another embodiment;

FIG. 3F illustrates an exemplary pillar having multiple top surfaces and multiple lateral surfaces, according to another embodiment;

FIG. 4A illustrates a lateral cross-sectional view of an exemplary pillared solar cell structure and incident light behaving as a photon stream, according to one embodiment;

FIG. 4B illustrates a lateral cross-sectional view of an exemplary pillared solar cell structure and incident light behaving as electromagnetic waves, according to one embodiment;

FIG. 4C illustrates a lateral cross-sectional view of an exemplary pillared solar cell structure and the capturing of electrons generated by absorbed photons, according to one embodiment;

FIG. 5 illustrates the diffraction effect of light around the edge of a thin sheet of paper;

FIG. 6 illustrates the diffraction effect of light through a thin slit;

FIGS. 7-18 illustrate exemplary processes for constructing a pillared solar cell structure, according to one embodiment;

FIG. 19 illustrates a lateral cross-sectional view of a prior art planar solar cell structure;

FIG. 20 illustrates a lateral cross-sectional view of an exemplary pillared solar cell structure incorporating self-aligned p/p+ junctions, according to one embodiment;

FIG. 21 illustrates a lateral cross-sectional view of an exemplary pillared solar cell structure incorporating a self-aligned p/p+ junction and the capturing of holes, according to one embodiment;

FIG. 22 illustrates a lateral cross-sectional view of an exemplary planar solar cell structure incorporating a self-aligned p/p+ junction, according to one embodiment; and

FIGS. 23-30 illustrate exemplary processes for constructing a self-aligned p/p+ junction, according to one embodiment.

It should be noted that the figures are not necessarily drawn to scale and that elements of similar structures or functions are generally represented by like reference numerals for illustrative purposes throughout the figures. It also should be noted that the figures are only intended to facilitate the description of the various embodiments described herein. The figures do not describe every aspect of the teachings disclosed herein and do not limit the scope of the claims.

### DETAILED DESCRIPTION

Prior art solar cell structures feature a planar P-N junction near the top surface of the cell structure. The P-N junction is the surface at which the doped upper portion of the substrate meets the un-doped lower portion of the substrate. The doped region above the P-N junction has an electric charge that is opposite to that of the region below the P-N junction. This charge polarity is maintained by the process of electron diffusion across the junction and creates an electric field within the region surrounding the P-N junction, called the depletion region.

For the purpose of simplifying explanations and illustrations, the present disclosure will characterize light using photons unless stated otherwise. The photovoltaic process begins when incident light hits the top surface of the photovoltaic cell. Incident photons either penetrate or reflect off the surface. Of the photons that penetrate the surface, photons having energies above a certain level, called the band gap energy level, are absorbed while photons with lower energies pass through the cell. Different types of semiconductor material have different band gap energy levels. When a photon is absorbed, the energy is transferred to a bound electron in the substrate, freeing it from its bound location and creating an electron-hole pair. Electrons are negative charge carriers while holes are positive charge carriers. Energy in excess of what is needed to free an electron is lost as heat. Free electrons close to the P-N junction are influenced by the depletion region's electric field and drift in the direction towards a region with higher electric potential. Depending on the distance the electrons have to travel, some electrons may recombine with nearby holes or become trapped in crystalline defects. In a complete circuit, the electrons that drift past the P-N junction into an external circuit can be harnessed as an electrical current. A complete circuit provides a return path for the electrons to travel back to the photovoltaic cell.

One of the drawbacks of harnessing solar energy in this manner is conversion inefficiency. The efficiency of a photovoltaic cell is calculated as the percentage of light energy converted into electrical energy from irradiated light. Of all the photons that strike the surface area of a solar cell, only a percentage of the total energy of the photons is converted into useable electrical energy. Efficiencies vary depending on the material of the substrate used to construct the photovoltaic cell. For instance, using silicon as the substrate, the theoretical limit is ˜31% efficiency. The current highest efficiency level achieved under laboratory conditions is ˜24% while the current level of efficiency in mass production is about ˜14-18%.

There are two aspects of energy conversion inefficiency that are common among the various types of prior art photovoltaic cells. One aspect relates to the wide spectrum of sunlight. The spectrum corresponds to the range of energies of the photons in the light. For silicon-based photovoltaic cells, a significant portion of the sunlight that reaches the Earth is composed of photons with energies significantly greater than the 1.1 eV band gap energy level of silicon. For these high energy photons, the excess energy—the difference in energy between these photons and the band gap energy—is lost as heat, instead of being converted into electrical energy. The photons with energies lower than the band gap energy level pass through the substrate and are not absorbed. Whether the energies from the photons are lost as heat or lost as pass-through photons, the effect is energy conversion inefficiency.

Another aspect of conversion inefficiency is observed when a number of the photons penetrate deep within the silicon substrate before they are absorbed to create electron-hole pairs. Since these free electrons are generated farther from the P-N junction, they typically recombine with nearby holes before they reach the P-N junction. Recombined electrons lose their energy and mobility either radiatively, by emitting a photon, or non-radiatively, by generating heat. Since these recombined electrons do not become part of an electrical current that can be harnessed by an external circuit, the energies of the absorbed photons are wasted, contributing to the overall energy conversion inefficiency.

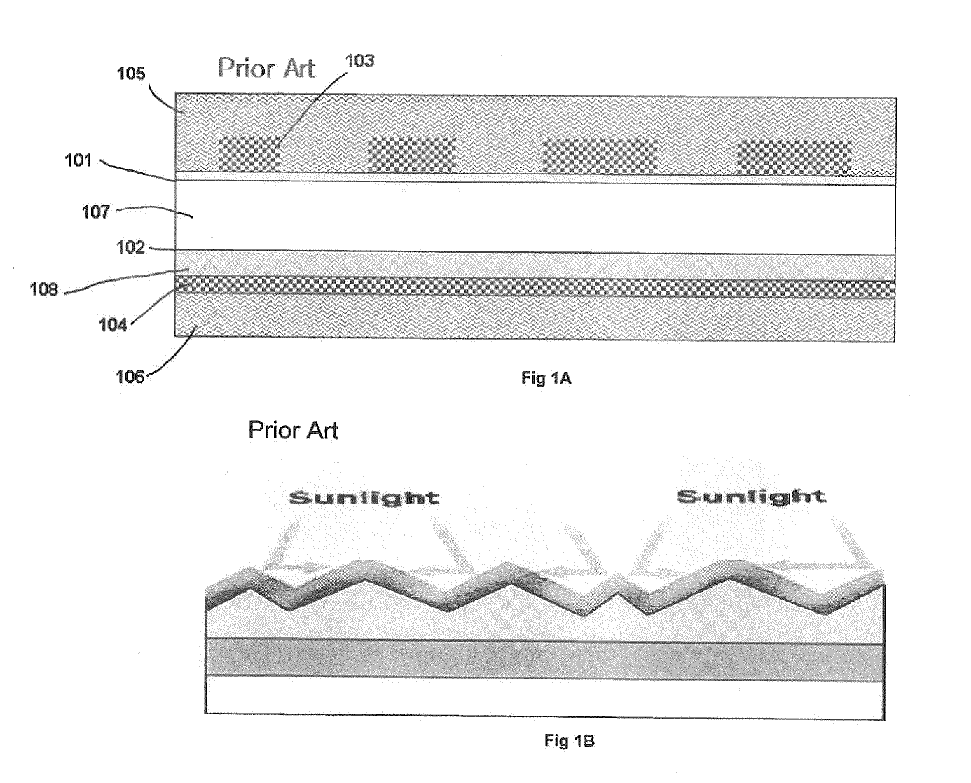

FIG. 1 illustrates a prior art design with the top P-N junction 101. Generally, a top P-N junction is created by doping a P-type substrate 107 with an N-type dopant. A P-N junction created with an N-type dopant is considered an “electron collector.” When energy from photons is absorbed by bound electrons in the semiconductor substrate, the bound electrons in valence band are excited into the conduction band where they are free to move around and electron-hole pairs are created. Since most electron-hole pairs are generated near the top surface of the cell structure, placing the N-doped P-N junction near the electron-hole pair generation sites facilitates electron collection. Additionally, some prior art designs feature a P/P+ junction 102 near the back surface of the solar cell structure to facilitate the collection of holes. Metal contacts 103, in contact with the region above the P-N junction 101, provide a path for the electrons to travel into an external circuit. Similarly, metal layer 104, in contact with the region below the P/P+ junction 102, provides a path for holes to travel into the external circuit. Together, the holes and electrons traveling through the external circuit have an electric current that can be harnessed for its electrical energy. Anti-reflective layers 105 and 106 are used to minimize light reflection.

Another solar cell structure of the prior art that improves upon the planar P-N junction near the top surface utilizes a textured surface. FIG. 1B illustrates such a design. The textured surface increases the surface area by which sunlight is captured by capturing reflections.

Yet another solar cell structure of the prior art that improves upon the planar P-N junction near the top surface utilizes a trench structure 109 below the surface, as illustrated in FIG. 1C. The drawback of such a structure is that the metal line blocks incoming light so that electron-hole pair generation is limited. The trench structure 109 increases junction area but light capture is limited because one side of the surface captures light.

In view of the foregoing, there exists a need to improve photovoltaic cell efficiency in capturing and converting light energy to electrical energy.

### Pillared Solar Cell Structure

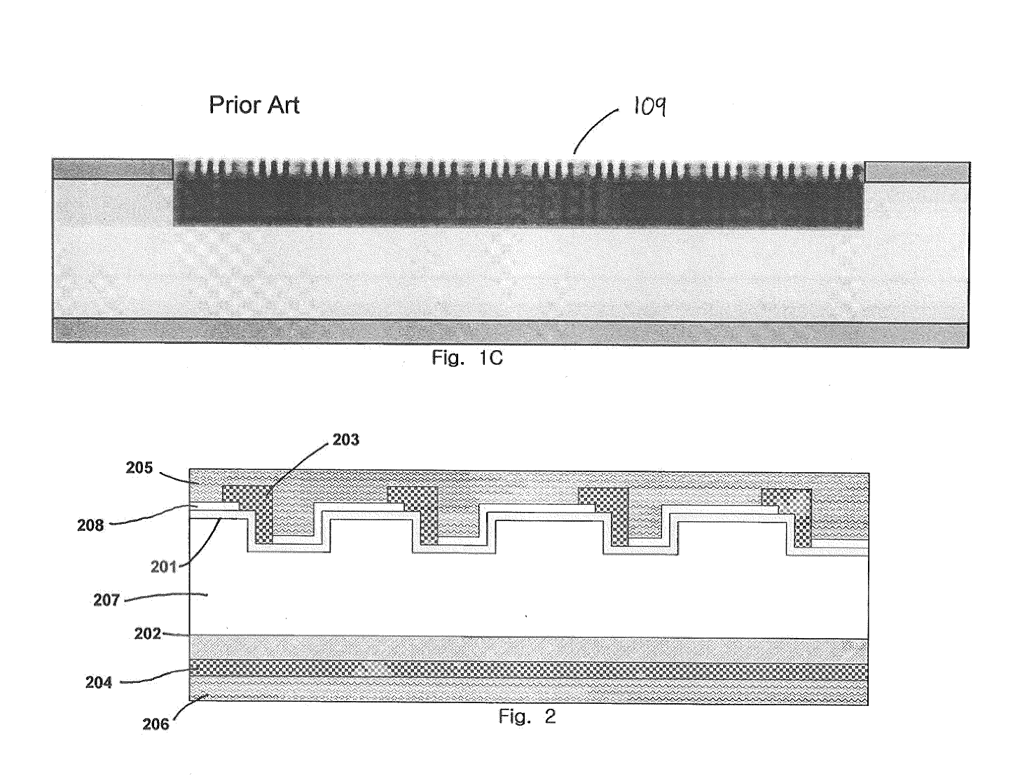

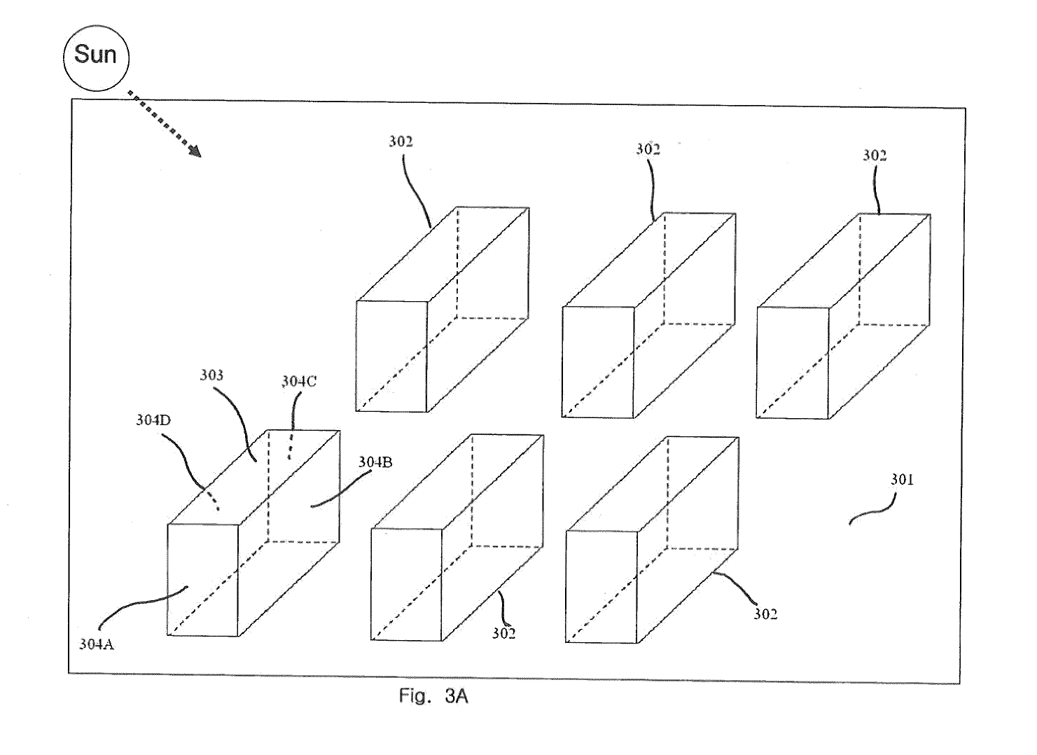

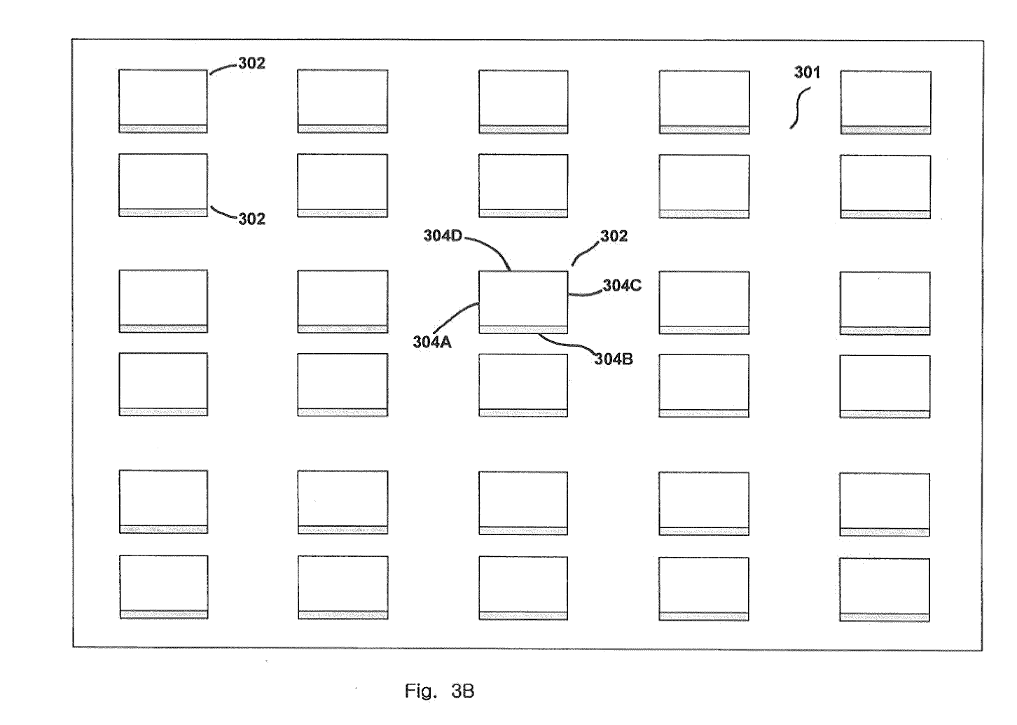

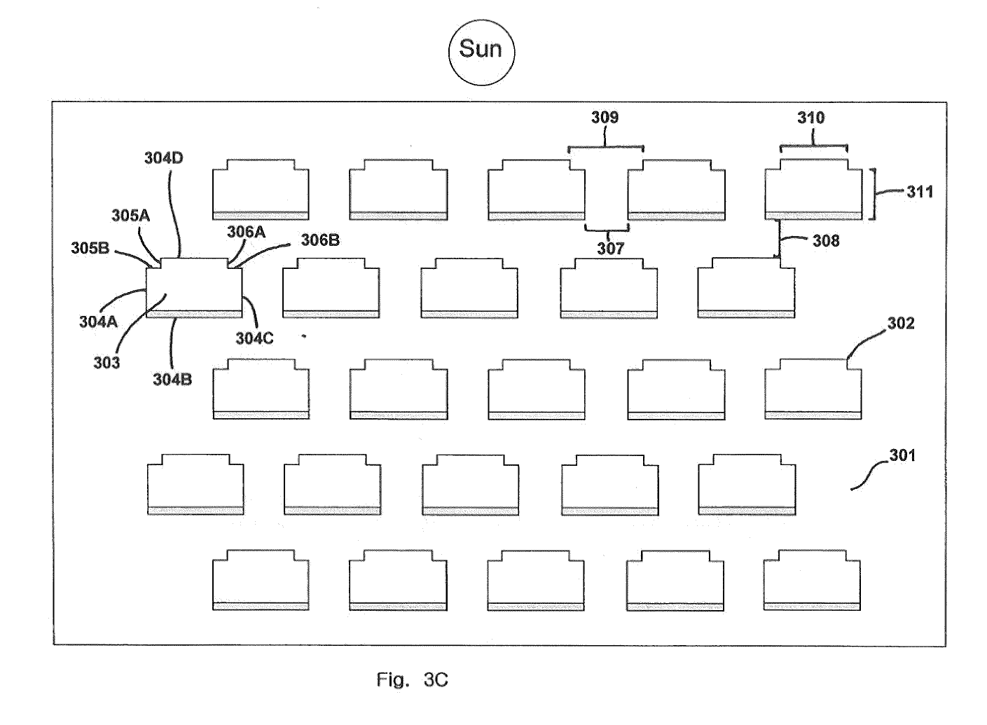

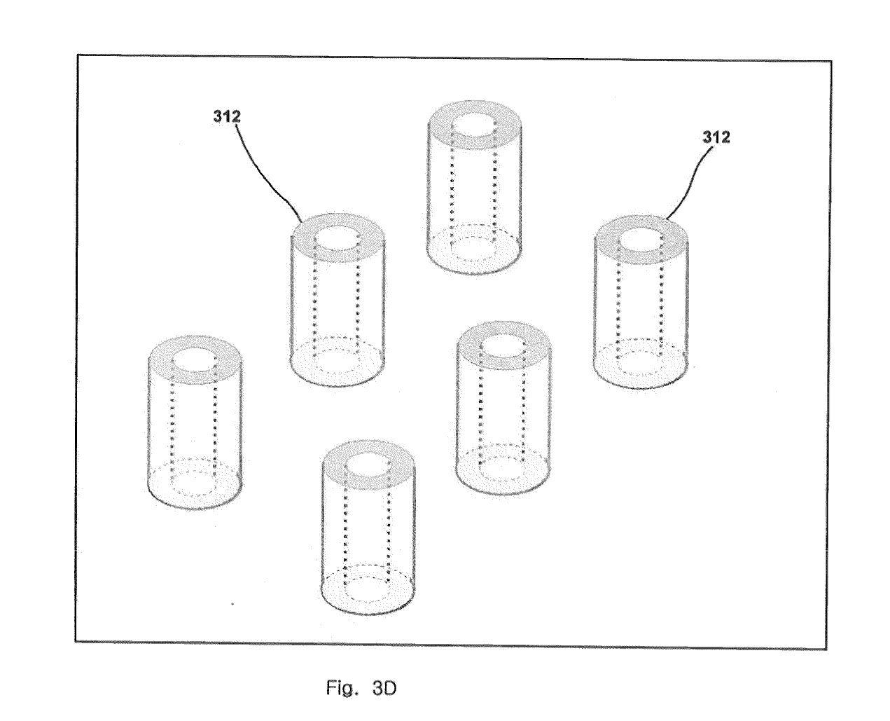

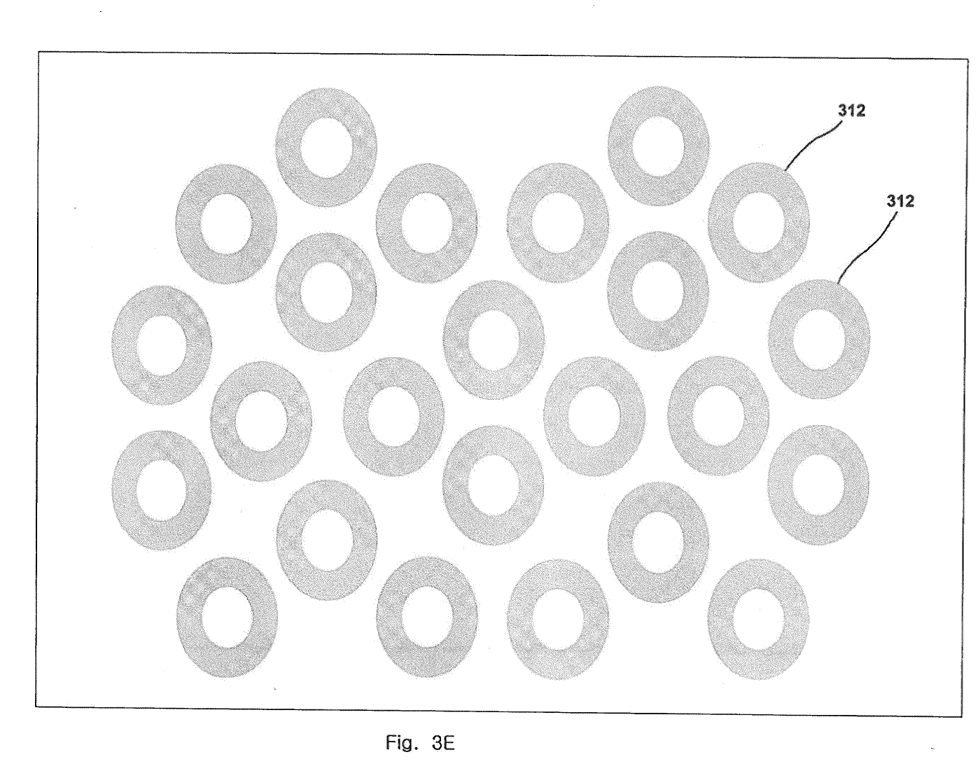

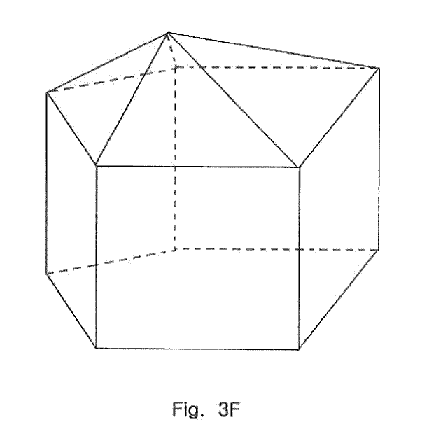

The pillared solar cell structure disclosed herein provides increased capture of electron hole pairs, and thereby increased electrical current, which in return increases energy conversion efficiency over prior art solar cell structures. FIG. 2 illustrates a lateral cross-sectional view of an embodiment of a pillared solar cell structure. The pillared solar cell structure 300 includes an array of three-dimensional pillars 302, as illustrated in FIG. 3A, arranged on base surface 301. FIG. 3B illustrates a top view of an exemplary embodiment of a pillared solar cell structure in which the pillars 302 are arranged in a grid-like manner on base surface 301. FIG. 3C illustrates a top view of another exemplary embodiment of a pillared solar cell structure in which pillar 302 are arranged in a staggered row pattern on base surface 301.

FIG. 2 illustrates a lateral cross-sectional view of an embodiment of a pillared solar cell structure. P-N junction 201 is the surface where the N-doped region meets the substrate 207. Consistent with one embodiment, P-N junction 201 may be created by doping a P-type substrate 207 with an N-type dopant while P/P+ junction 202 may be created by doping P-type substrate 207 with a P-type dopant Metal contacts 203 are in contact with the region above the P-N junction 201 while metal layer 204 is in contact with the region below the P/P+ junction 202. These metal contacts may be used to connect to an external circuit Anti-reflective layers 205 and 206 are used to minimize light reflection. Layer 208 can be a silicon nitride on an oxide or a dielectric layer or a combination of dielectric layers.

A three-dimensional view of an exemplary embodiment of a pillared solar cell structure having pillars 302 arranged on base surface 301 is illustrated in FIG. 3A. According to one embodiment, each pillar includes a top surface 303 substantially parallel to base surface 301 and four lateral surfaces 304A, 304B, 304C, 304D, each about perpendicular to top surface 303. Consistent with one embodiment, adjacent lateral surfaces meet about perpendicularly. For instance, surfaces 304A and 304B are adjacent to each other while both surfaces are adjacent to top surface 303. It is contemplated that a pillar may include any number of lateral surfaces and one or more top surfaces as shown in FIG. 3D and FIG. 3F. It is also contemplated that the lateral surfaces and the one or more top surfaces of a pillar structure may be configured to meet at various angles to optimize surface exposure to light irradiating from a pre-specified direction.

It is contemplated that the top or lateral surfaces of pillars may be wavy or curvy. A cell structure having pillars 312 with a curved lateral surface is illustrated in FIG. 3. One embodiment contemplated, but not illustrated, features pillars with an hour-glass shape. One embodiment contemplated, but not illustrated, features pillars with a combination of curved and flat surfaces.

According to one embodiment, the lateral surface 304B includes a metal coating or layer that features a mirror-like reflective quality. To help illustrate the benefits of a metal coating, FIG. 3A shows sunlight irradiating from a direction in which the sunlight is incident on lateral surfaces 304D and top surfaces 303 of the pillars. As a result of this orientation, surface 304B is in the shadow region since there is no direct incident sunlight. The light incident on surface 304B is light reflected from other pillars or from the base surface 301. However, due to the mirror-like reflective quality of lateral surface 304B, almost all of the light incident to 304B will reflect back towards the surface of 304D and or other pillars or the base surface 301, thereby, creating a light trapping mechanism. The more light that is reflected back towards other pillars' surfaces or the base surface 301, the more likely the light will penetrate these surfaces and become absorbed by the substrate. Consistent with one embodiment, a metal coating or layer is created as part of every contact 203. Consistent with another embodiment, a metal coating or layer is created on some, but not all, pillars 302. A balance of cost versus performance benefits may dictate which and how many pillars feature a metal coating or layer. Note that all the surfaces, such as 303, 304A, 304B, 304C, and 304D, may behave like mirrors for the incoming light.

FIG. 3B and FIG. 3C illustrate top views of contemplated arrangements of pillars 302 on base surface 301. FIG. 3B illustrates a grid-like arrangement while FIG. 3C illustrates a staggered row arrangement. Arranging the pillar structures in a staggered row pattern reduces the chances of a pillar structure being covered by shadows created by other nearby pillars. It is contemplated that the pillars can be arranged in other fashions to optimize surface area exposure to irradiated light. Additionally, the pillars 302 in FIG. 3C demonstrate a contemplated embodiment in which there are eight lateral surfaces—304A, 304B, 304C, 304D, 305A, 305B, 306A, and 306B—to optimize surface area exposure to incident sunlight. Consistent with one embodiment, the distance 307 between two adjacent pillars is less than 4 μm. Consistent with one embodiment, the distance 309 between two adjacent pillars is less than 5 μm. Consistent with one embodiment, the distance 308 between surface 304D and 304B of two staggered pillars is less than 3 μm. Consistent with one embodiment, the width 310 of surface 304D is less than 8 μm. Consistent with one embodiment, length 311, as measured between surfaces 304B and 304D of the same pillar, is less than 10 μm. Various other pillar dimensions and spacing distances are contemplated.

In another embodiment, FIG. 3D shows another three-dimensional view of the structure. Whereas FIG. 3A shows rectangular pillars 302, FIG. 3D shows cylindrical pillars 312. Any shape of the pillar structure is possible through design layout of the cell, using the same processing techniques. FIG. 3E shows a contemplated arrangement of pillars 312.

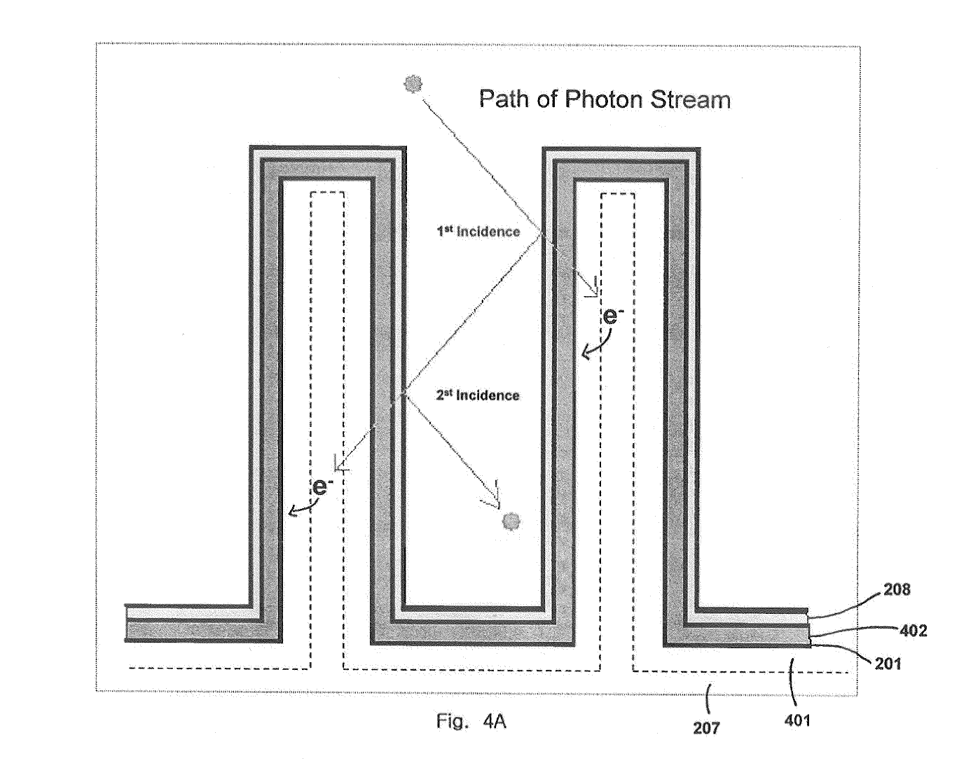

FIG. 4A to FIG. 4C illustrate cross-sectional views of adjacent pillars. They illustrate the interactions of incident sunlight, both in the form of photons and electromagnetic waves, with the pillars. Wave-particle duality is a concept that all energy and matter behave like waves and particles at the same time. This is a central concept in quantum mechanics because duality of behavior is more readily observable on the quantum-scale. Light energy is characterized as a particle, particularly a photon, because it has a fixed, discrete energy level and each color of light has its own unique energy level. Additionally, the intensity of light can be increased or decreased by varying the number of photons present. However, at the same time, light also exhibits behavior corresponding to parameters such as wavelength and phase, which are wave properties. A well-known experiment that explores the wave-like properties of light is the slit experiment, which will be discussed in reference to FIG. 4B.

FIG. 4A illustrates a cross-sectional view of adjacent pillars. Consistent with one embodiment, the shaded region 402 is the portion of substrate 207 that is doped with an N-type dopant and P-N junction 201 is the surface just below the N-doped region 402 of the substrate. Layer 208 is an oxide or dielectric layer. The region underneath P-N junction 201 and delimited by dotted lines is the depletion region 401. The depletion region 401 is the region in which an electric field perpendicular to the P-N junction 201 is created and maintained by a charge polarity. Particles have a natural tendency to diffuse from a region of higher concentration to a region of lower concentration. The charge polarity is the result of constant electron diffusion across the P-N junction.

A light stream in the form of photons is reflected between the lateral surfaces 304A and 304C of adjacent pillars. At the point of first incidence, some of the incident photons penetrate the lateral surfaces and are absorbed to create electron-hole pairs, while some photons are reflected off of the surface and continue on a trajectory towards the point of second incidence. Photons that are reflected at the point of first incidence may subsequently be absorbed at the point of second incidence to create electron-hole pairs near that location. Electrons arising from electron-hole pairs are free electrons because they have absorbed the energy of a photon to gain mobility. Free electrons created within the depletion region 401 are swept across the P-N junction 201 into the N-doped region 402 by the electric field. Also, free electrons generated close to the depletion region 401 may diffuse into the depletion region 401 and be swept by the electric field. Once in the N-doped region 402, the free electrons may travel through metal contacts (not shown in FIG. 4A) into an external circuit as an electric current to provide electrical energy. While FIG. 4A illustrates two points of incidence for an exemplary trajectory of a given stream of photons, it should be appreciated that continuing the illustrated trajectory will yield numerous other points of incidence, points at which the photons may be absorbed to generate electron-hole pairs. Effectively, the lateral surfaces 304A and 304C of adjacent solar cells, along with the base surface 301, create a light trapping mechanism in which the chances of light being absorbed to create an electron-hole pair is significantly improved. In contrast, photons incident on the planar surface of a prior art solar cell structure are either absorbed or reflected into the air after the first point of incidence.

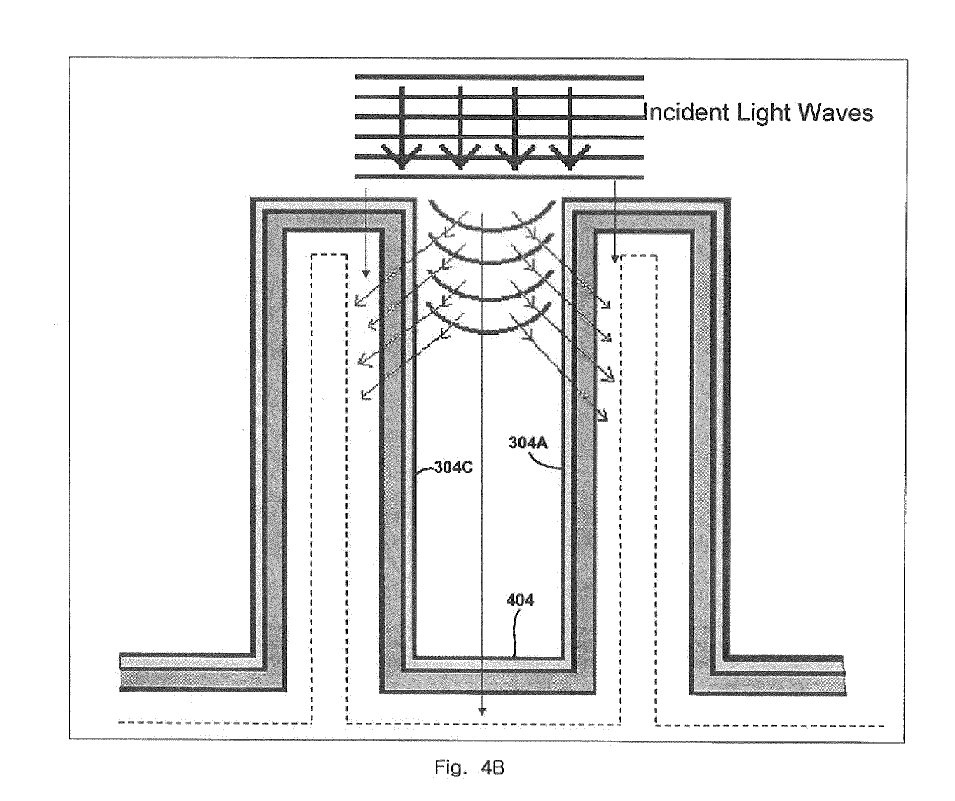

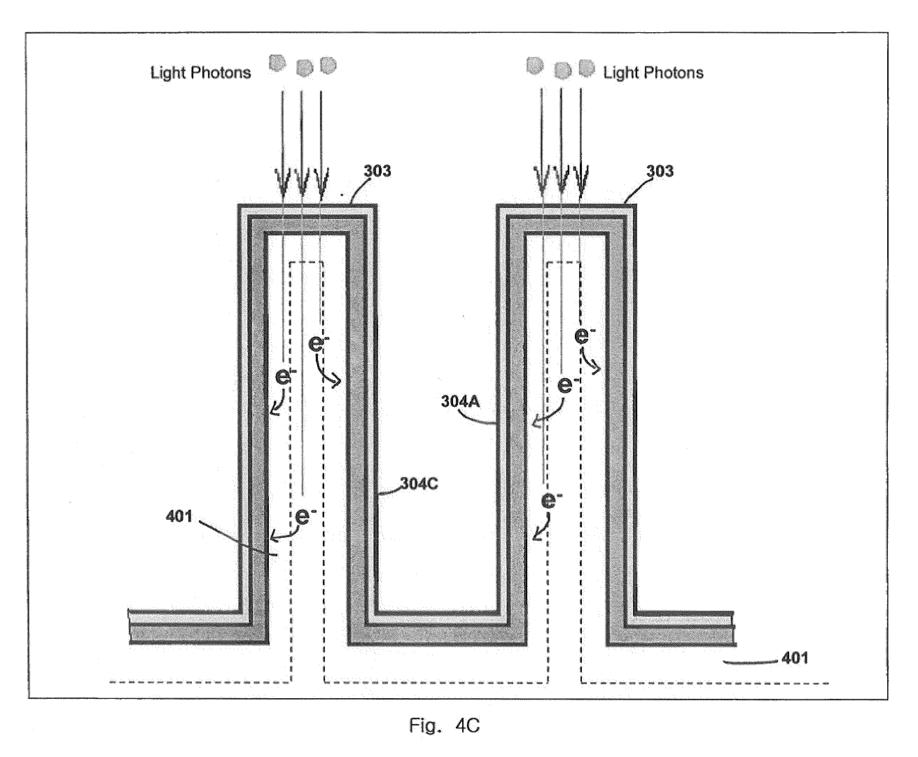

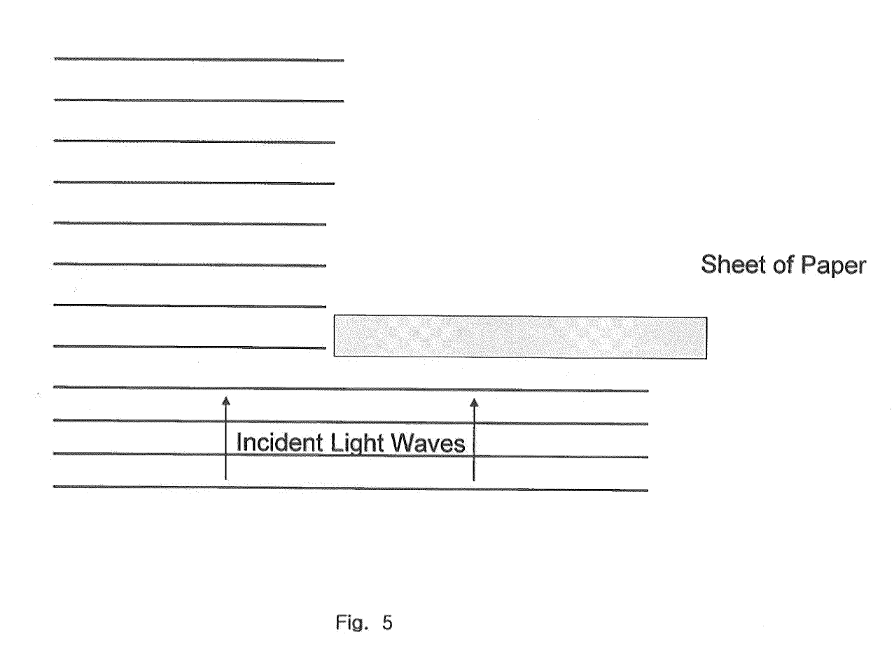

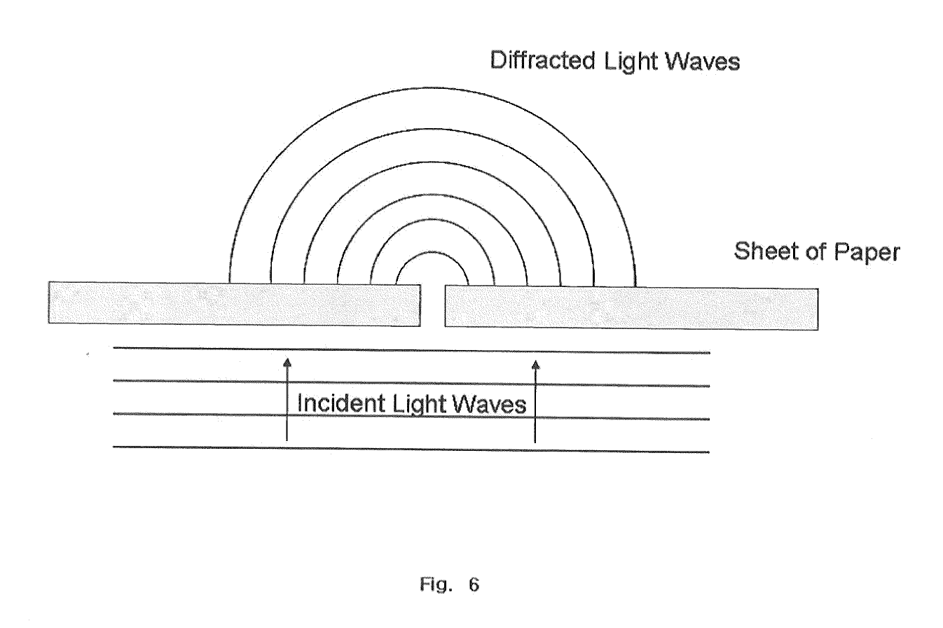

As mentioned earlier, light exhibits both wave-like and particle-like behavior. These wave-like characteristics become more apparent through interactions observed on the quantum scale. Take light diffraction for instance. Diffraction is a wave-like characteristic that causes light to bend around the edge of an object. When a beam of light shines perpendicularly against a sheet of paper such that a portion of the beam travels beyond the edge of the sheet, the portion of light traveling immediately adjacent to the edge of the paper actually bends slightly towards the sheet. FIG. 5 illustrates this effect. The bending is so slight that it is often unnoticeable. Taking wave interactions to a much smaller scale enhances this effect significantly. Consider shining a beam of light perpendicularly against a very narrow slit made in the center of the sheet of paper so that a very small portion of the light beam passes through the slit onto a nearby wall. What will be readily observable is a band of light, much wider than the slit itself, projected onto the wall such that the center of the band has the highest intensity. FIG. 6 illustrates this effect. This demonstrates the wave-light diffraction property of light.

The amount of bending of light depends on the relative size of the light's wavelength to the size of the opening. If the opening is much wider than the light's wavelength, the bending is almost unnoticeable. This is the case when light is shone around the edge of a sheet of paper and the opening is considered to be almost infinitely bigger than the lights wavelength. When the opening and the light's wavelength are closer in size or equal, the amount of bending is considerable. This is the case in the above slit experiment.

FIG. 4B illustrates how the pillared cell structure takes advantage of the diffraction effect of light to increase the effective surface area for capturing more light. 304C and 304A are the lateral surfaces of two adjacent pillars. 404 is the base surface between the two adjacent pillars. Light waves are shown to strike the top surfaces of the pillars perpendicularly. The space between the top surfaces of the pillars acts as a narrow slit for the incident light waves to enter. Consistent with an embodiment, the distance 403 of the space between two adjacent pillars is less than 3 μm. Light waves entering the space between the pillars are bent towards the lateral surfaces of the pillars due to diffraction. The light that hits the lateral surfaces of the pillars may be absorbed by the substrate to create electron-hole pairs. By taking advantage of the diffraction effect of light to bend the light towards the lateral surfaces, the effective surface area for capturing the entering light is the total surface area of surfaces 304C, 304A and 404. The amount of light (Lₘₐₓ) that can be captured is the product of irradiance (IR) and surface area (SA):

Lₘₐₓ=IR×SA

Irradiance is the amount of light per surface area unit at any given time. Thus, by increasing the effective surface area (SA) for the same irradiance (IR), more light (Lₘₐₓ) can be captured at any given time. In contrast, if the light waves entering the gap were not bent towards the lateral surfaces, only the surface area of surface 404 would contribute to capturing the entering light and Lₘₐₓ would be reduced dramatically. Consistent with one embodiment, the pillars are arranged in a close manner to take advantage of the diffraction effect of light, allowing a pillared solar cell structure to capture more light than the conventional solar cell structure, and thereby, to achieve a higher energy conversion efficiency.

As mentioned earlier, photons travel to various depths within the substrate before they are absorbed to create electron-hole pairs. This becomes a problem for prior art solar cell structures when the photons penetrate so deeply within the substrate that even though these photons are absorbed, their energies cannot be converted to electrical energy. For instance, when photons are absorbed, their energies are transferred to previously bound electrons, giving them mobility to move around freely. Free electrons generated within the depletion region 401 are swept across the P-N junction 201 into the N-doped region 402 by the electric field. Free electrons generated close to the depletion region 401 may diffuse into the depletion region 401 and also be swept by the electric field. Once in the N-doped region 402, the free electrons may travel through metal contacts (not shown in the figure) into an external circuit as an electric current to provide electrical energy. However, for free electrons that are generated far from both the P-N junction 201 and the depletion region 401, these free electrons would have to diffuse a relatively long way before they reach the depletion region 401. These electrons usually recombine with nearby holes and do not become part of the electrical current that can be harnessed by an external circuit. Thus, the energies of the photons absorbed deep within the substrate are not properly converted into useable energy by prior art solar cell structures.

In contrast, the pillared solar cell structure disclosed herein allows free electrons generated at various depths within the pillars to be captured and harnessed as electrical energy. FIG. 4C illustrates this mechanism. 304A and 304C are the lateral surfaces of a pillar. Light photons penetrate the top surfaces 303 of the pillars and are absorbed at various depths within the pillars to generate free electrons. Since depletion region 401 extends laterally from surfaces 304A and 304C, a free electron generated at any depth within the pillar is generally within, or in close proximity to, the depletion region 401, where electrons can be readily swept into an external circuit as part of an electric current to provide electrical energy.

Note that the energy band structure of the pillar cell structure will differ from the bulk silicon energy band structure at the interface of the sidewall surface. Thereby the electron capture efficiency will be increased.

### Method of Fabricating Pillared Solar Cell Structure

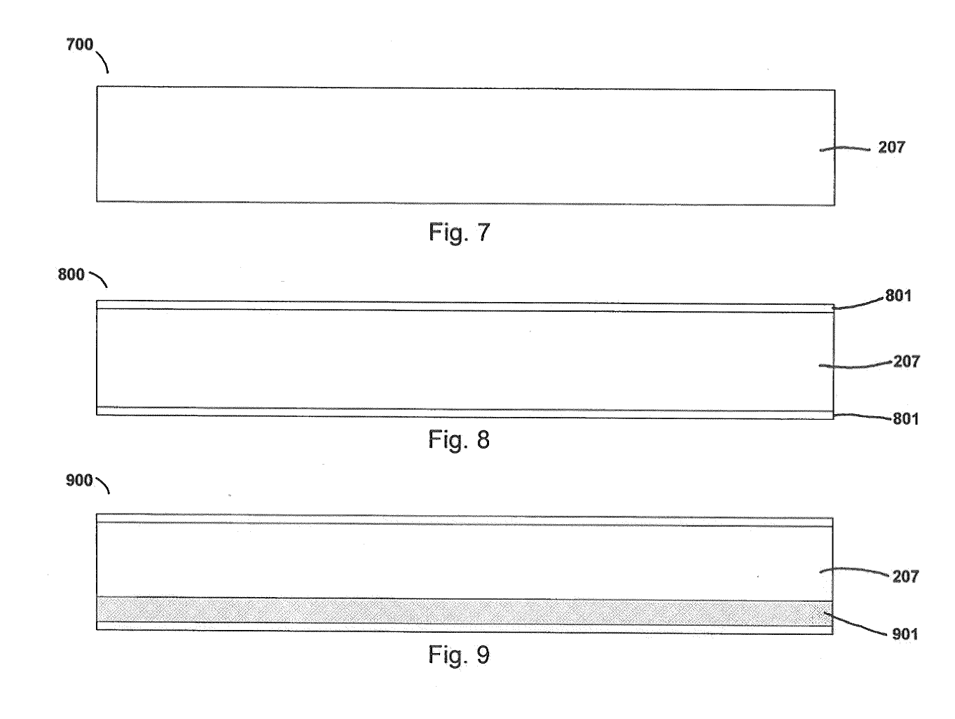

FIGS. 7-19 illustrate exemplary processes for constructing a pillared solar cell structure on a semiconductor wafer according to an embodiment. FIG. 7 shows a semiconductor substrate 207 in which the pillared solar cell structure in FIG. 2 is formed. There are several advantages to forming the pillars from a semiconductor substrate. Since the pillars can be formed using low-cost masking and etching techniques, the cost of pillared solar cell devices can be significantly reduced. Furthermore, P-N junctions formed on a semiconductor substrate have substantially less defects compared to those formed on thin-film structures. As mentioned earlier, electrons can become trapped in these defects. Trapped electrons do not contribute to the overall electric current that is generated. Consistent with an embodiment, substrate 207 is a P-type substrate. It is understood that in other embodiments, substrate 207 may be an N-type substrate.

FIG. 8 illustrates that a layer of screen oxide 801 is grown on substrate 207 using thermal oxidation processes. Optionally, a layer of oxide 801 may be deposited on substrate 207 by chemical vapor deposition method. Consistent with one embodiment, oxide layer 801 may have a thickness in the range of 60-2000 Å. Optionally, a layer of silicon-nitride, not shown in FIG. 8, may be deposited on oxide layer 801. Consistent with one embodiment, the silicon-nitride layer may have a thickness in the range of 500-1500 Å.

FIG. 9 illustrates forming a P+ region 901 within P-type substrate 207. Using ion implantation, a high dose of boron atoms (4-5×10¹⁴ atoms/cm² at 40˜60 keV) may be implanted at the backside of the substrate 207 and driven in a high temperature furnace of 1000˜1100° C. for 1˜24 hours to diffuse the doping material. It is understood that doping may be performed by the process of diffusion using BBR₃ as the doping material.

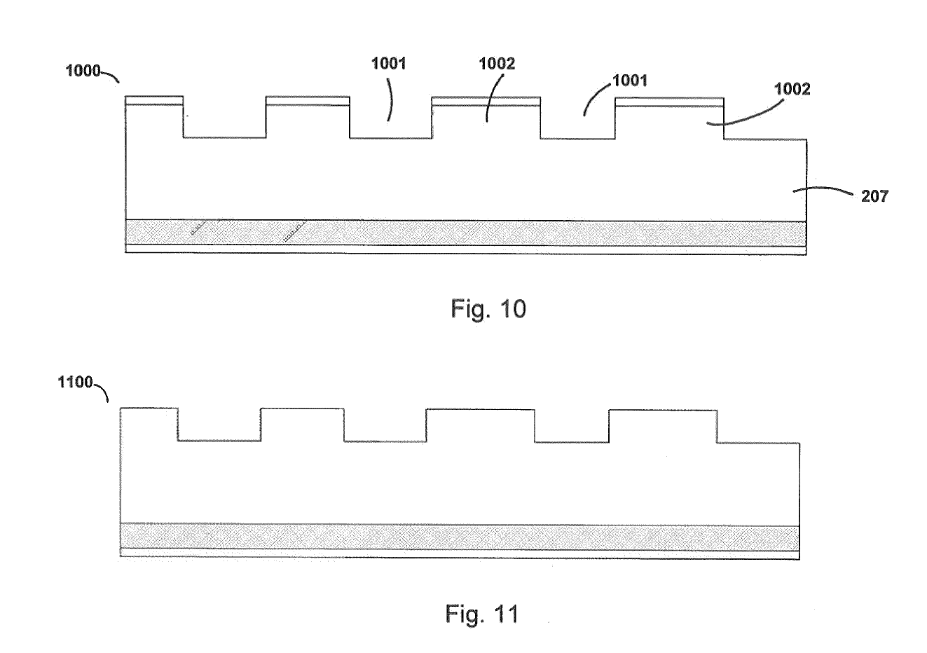

FIG. 10 illustrates the structure 1000 after using masking and etching. Trenches 1001 are formed in substrate 207, forming an array of pillars 1002. According to one embodiment, the trench depth is between 1 μm and 20 μm. After trenches 1001 are formed, a layer of oxide having a thickness of, e.g., 150˜500 Å, is grown over the structure 1000 (not shown in figure). This oxide is grown to remove any defects formed during the trenching process.

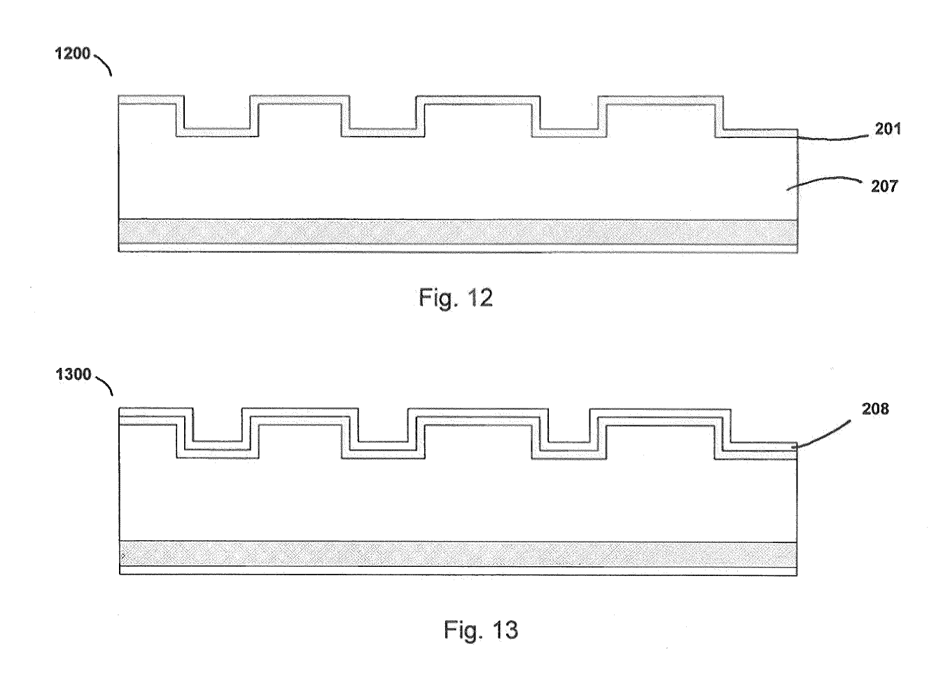

FIG. 11 illustrates the structure 1100 after removing all the oxide and nitride from the top of the semiconductor wafer. FIG. 12 illustrates the structure 1200 after forming an N-type junction 201 on the substrate 207. N-type doping may be performed by phosphorous implantation with a concentration of 2˜14×10¹⁴ atoms/cm². Alternatively, N-type doping may be performed by diffusing a dopant such as POCl₃. Next, a thermal anneal is performed at the temperature of, e.g., 850-980° C. for a predetermined time period (e.g., 30 minutes). It is understood that a layer of polysilicon having a thickness in the range of, e.g., 300-3200 Å, may optionally be deposited on the structure 1100 prior to diffusion of the N-type dopant such as POCl₃.

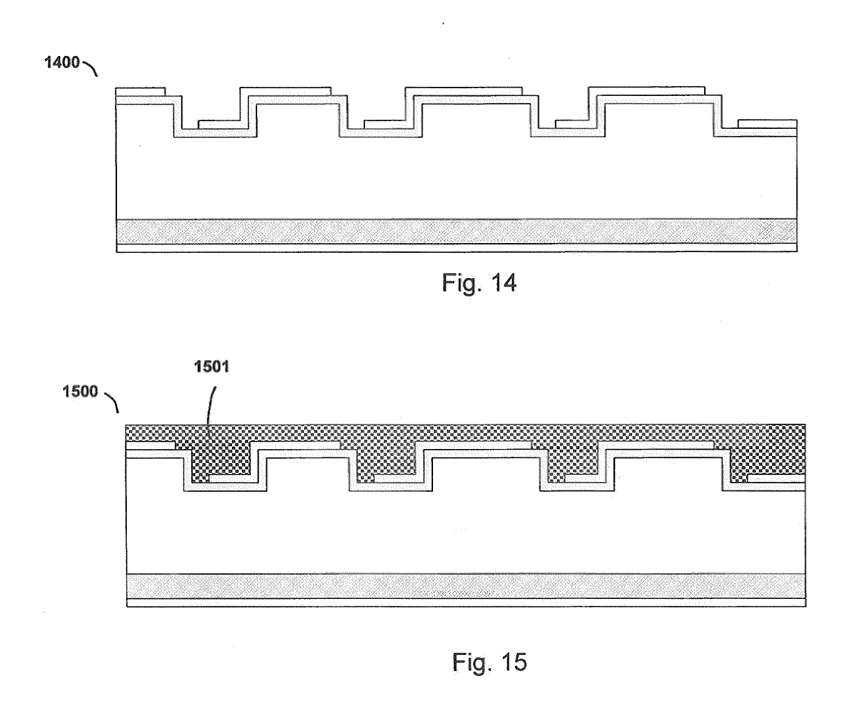

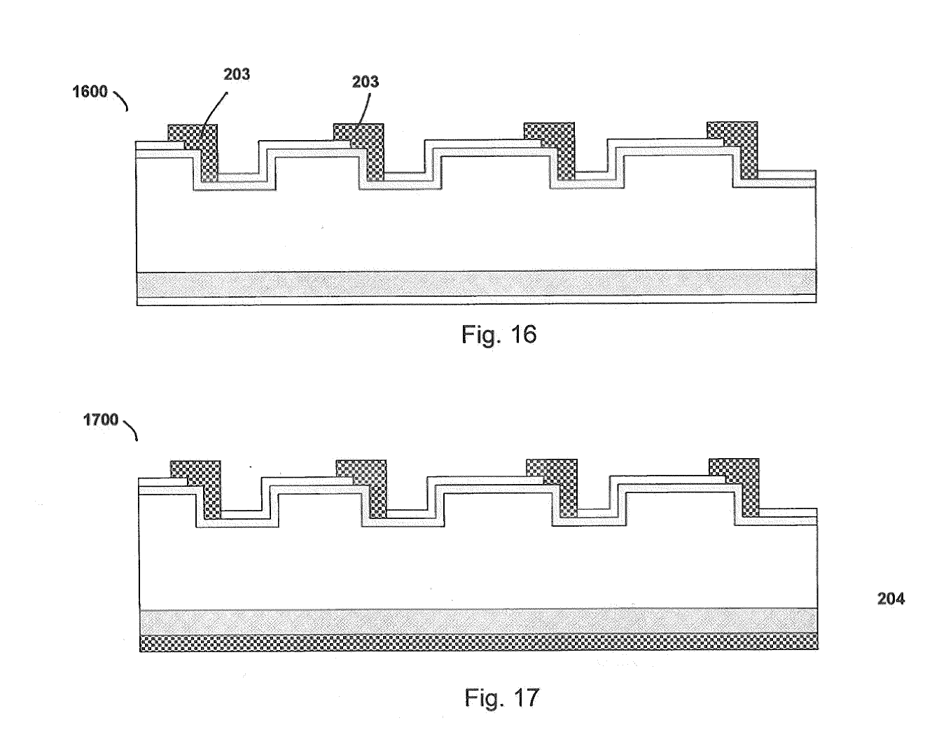

Next, an antireflection layer of a silicon nitride on oxide or a combination of dielectric layers 208 having a particular thickness (e.g., 500˜5000 Å), is thermally grown or deposited as shown in FIG. 13. Note that the thermal oxide layer thickness is typically less than 100 A or can be a native oxide. Using standard photo-resist masking and patterning techniques, portions of layer 208 are removed from the regions not covered by a mask to form the structure 1400, as shown in FIG. 14. A metal, such as aluminum, copper, or silver, is then deposited or plated on top of the structure to form a metal layer 1501, as shown in FIG. 15. Again, using standard photo-resist masking and patterning techniques, the metal layer 1501 is etched to form metal contacts 203 and front metal lines not shown here, as shown in FIG. 16.

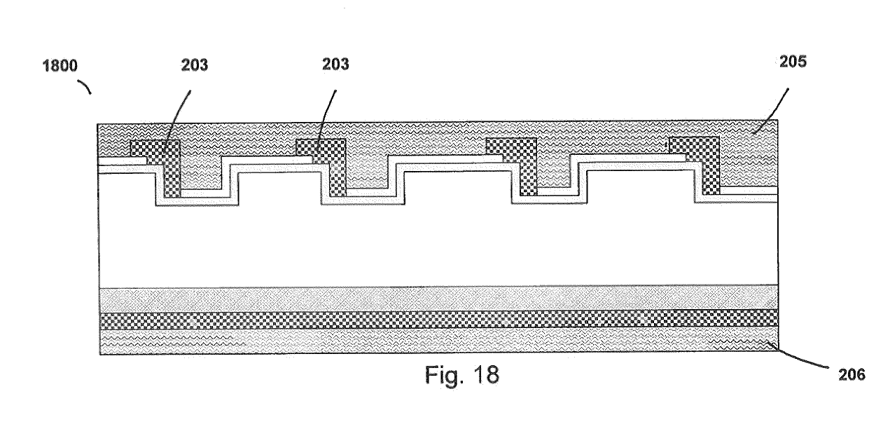

A metal such as aluminum or copper or nickel doped is deposited over the backside of the wafer to form metal layer 204, as shown in FIG. 17. Note that any oxide or any dielectric layer of the backside of the wafer is substantially or completely removed before depositing the metal layer, which is not shown in FIG. 17. Next, a passivation layers 205 and 206 are formed by depositing an oxide or anti-reflective material over structure 1700, as shown in FIG. 18. Finally, using standard photo-resist masking and patterning techniques, a portion of the passivation layer is removed to allow a external connection point to one or more of the metal contacts 203. The contact points are not shown in FIG. 18. Although the above description only refers to a single passivation layer, it is understood that additional anti-reflective layers may be formed by a CVD method. Also, it is understood that some of the process can be reduced or omitted and that other process combinations are possible.

### Self-Aligned P/P+ Junction

The solar cell structure incorporating self-aligned P/P+ junctions described herein provides increased energy conversion efficiency over the prior art solar cell structures. As mentioned earlier, when a photon is absorbed by the substrate of the solar cell, an electron-hole pair is generated. Unlike an electron, a hole is not an actual particle. A hole is actually the absence of an electron, giving it a positive charge, and contributes to the current as a positive charge carrier. However, electrons are generally the preferred charge carrier because they have higher mobility compared to holes. In a semiconductor, both holes and electrons contribute to the overall electrical current that is generated. In order to make a backside contact, some prior art designs feature a P/P+ junction 102 near the back surface of the solar cell structure to facilitate the collection of holes, as illustrated in FIG. 19. However, prior structures have a 200 um thickness/distance between the P-N junction at the front and the P/P+ junction at the backside contact, which increases the resistance value and decreases the hole capture efficiency. A P/P+ junction 102 operates in a fashion similar to that of a P-N junction. The P+ region 108 below the P/P+ junction 102 has a more negative ionic charge compared to the substrate 107 above the P/P+ junction. This charge polarity is maintained by the constant diffusion of holes across the junction and creates an electric field within the region surrounding the P/P+ junction, called the depletion region. Holes that diffuse into the depletion region are swept across the P/P+ junction by the electric field. Once in the P+ region 108, the holes may travel through metal contacts 103 into an external circuit as part of an electric current to provide electrical energy. However, there are drawbacks to this prior art design.

One of the drawbacks is the distance the holes have to travel before they reach the depletion region surrounding the P/P+ junction. Electron-hole pairs are usually generated in the top portion of the substrate 107 while the depletion region surrounding the P/P+ junction is located in the bottom portion of the substrate 107. This means that the holes have to diffuse from the top portion of the substrate to the bottom portion of the substrate before it reaches the depletion region, where they can be swept across the P/P+ junction by the electric field. One may consider making the substrate thinner. Typically the dominant thickness is about 200 um and every effort is made to reduce thickness. However, this approach is limited by process technology, and in some cases, would make the solar cell structure too brittle for certain applications. A hole is diffusing towards the depletion region, there is a chance that the hole will recombine with a nearby electron. The longer the distance the holes have to travel, the higher the chances that the holes will recombine. Recombined holes do not contribute to the hole current. As a result, many of the holes from the electron-hole pairs are not properly converted into useable electrical energy.

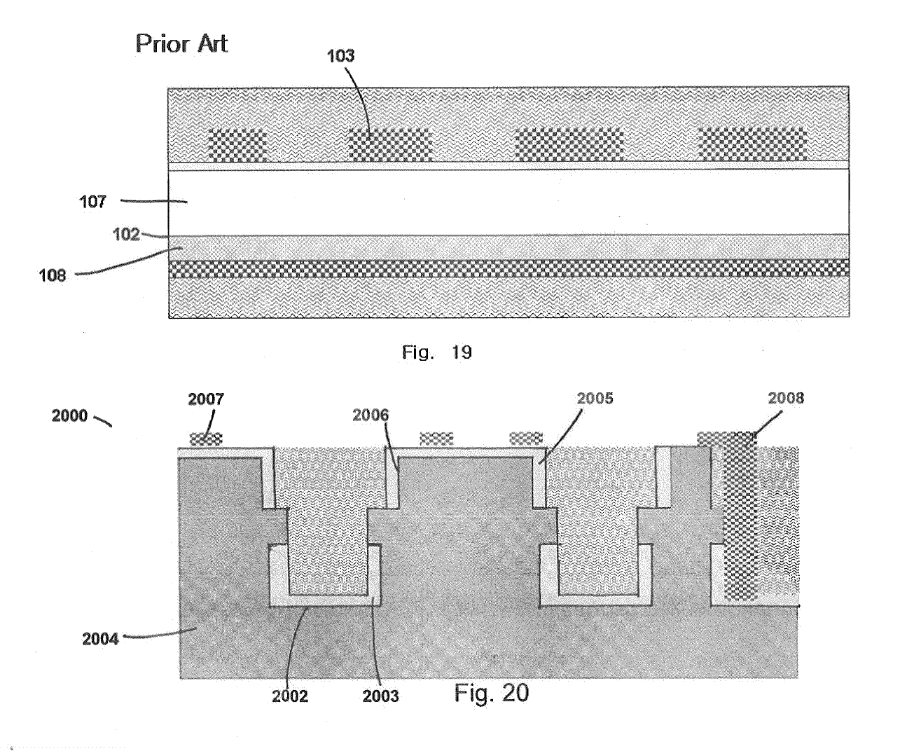

FIG. 20 illustrates a lateral cross-sectional view of an exemplary embodiment of a solar cell structure 2000 incorporating self-aligned P/P+ junctions 2002. According to one embodiment, P+ regions 2003 are portions of the P-type substrate 2004 that are doped with a P-type dopant while N-doped regions 2005 are portions of the P-type substrate 2004 that are doped with an N-type dopant. P/P+ junctions 2002 are the surfaces where P+ regions 2003 meet the substrate 2004. P-N junctions 2006 are the surfaces where N-doped regions 2005 meet the substrate 2004. Metal contacts 2007 provide a path for electron carriers to travel into an external circuit (not shown in figure). Metal contacts 2008 provide a path for hole carriers to travel into the external circuit.

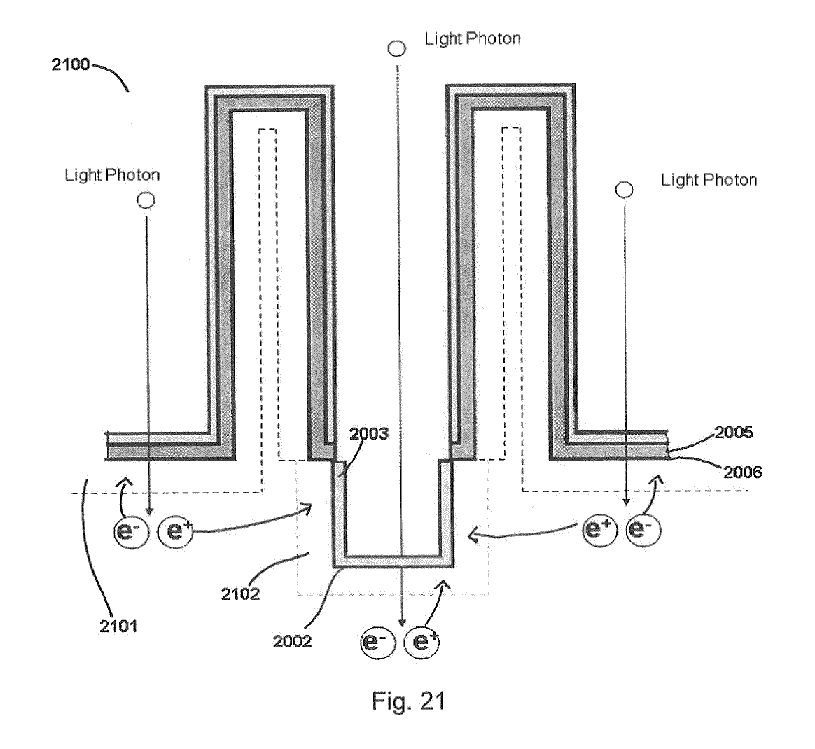

FIG. 21 illustrates holes and electrons being captured in an exemplary embodiment of a pillared solar cell structure incorporating a self-aligned P/P+ junction 2002. Light photons are shown striking and penetrating the surface of the solar cell structure 2100 and creating electron-hole pairs at various depths of the substrate 2004. Despite the electron-hole pairs being generated close to the top surface of the structure 2100, the holes are close enough to the depletion region 2102 that they can diffuse into the depletion region 2102 without recombining. Once inside the depletion region 2102, the holes are swept across the self-aligned P/P+junction 2002 into the P+ region 2003 by the electric field. From the P+ region 2003, the holes can travel to an external circuit through metal contacts (not shown in figure). Similarly, electrons from electron-hole pairs can diffuse into the depletion region 2101 and be swept across the P-N junction 2006 into N-doped region 2005. The self-aligned P/P+ junction 2002 allows holes to be collected and harnessed as a hole current without having the holes travel to the bottom portion of the solar cell structure and risk recombination. It is contemplated that a solar cell structure may incorporate both self-aligned P/P+ junctions and a P/P+ junction at the bottom of the cell structure.

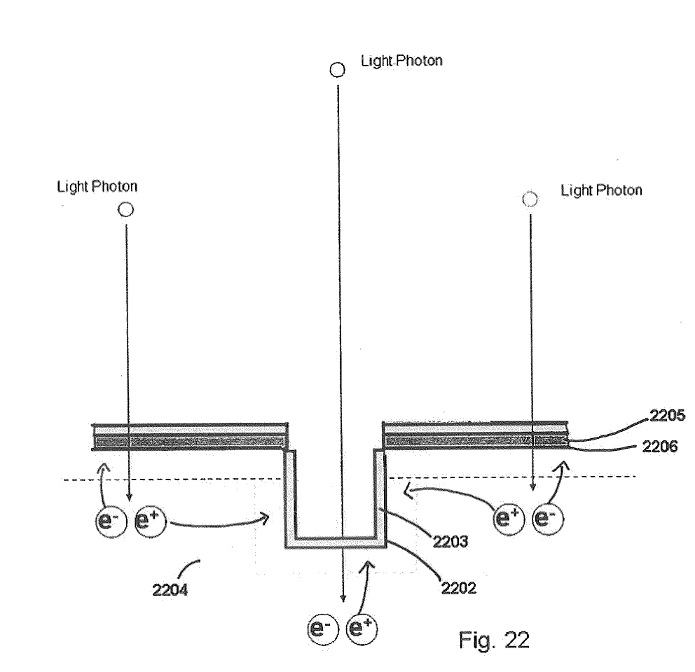

Although FIG. 21 illustrates a pillared solar cell structure incorporating self-aligned P/P+junctions, it is contemplated that self-aligned P/P+ junctions may be implemented independent of pillared solar cell structures. FIG. 22 illustrates an exemplary embodiment of a planar solar cell structure incorporating self-aligned P/P+ junctions. P+ regions 2203 are portions of the P-type substrate 2204 that are doped with a P-type dopant while N-doped regions 2205 are portions of the P-type substrate 2204 that are doped with an N-type dopant. P/P+ junctions 2202 are the surfaces where P+ regions 2202 meet the substrate 2206. P-N junctions 2206 are the surfaces where N-doped regions 2205 meet the substrate 2204.

### Method of Fabricating a Pillared Solar Cell Structure Incorporating Self-Aligned P/P+ Junctions

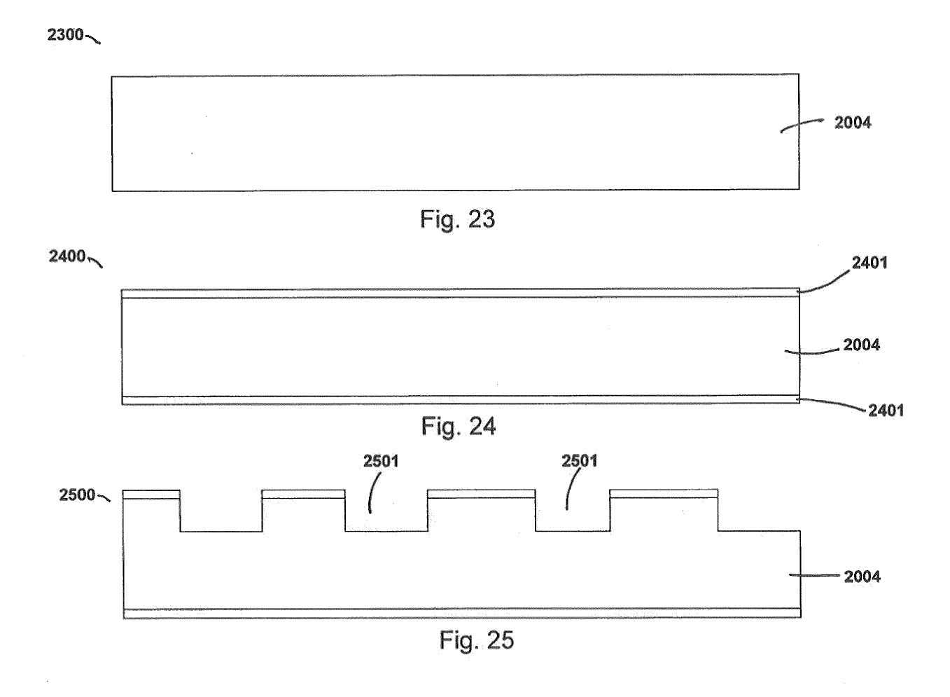

FIGS. 23-32 illustrate an exemplary process for constructing a pillared solar cell structure incorporating self-aligned P/P+ junctions on a semiconductor wafer according to an embodiment. FIG. 23 shows a semiconductor substrate 2004 in which the pillared solar cell structure in FIG. 20 is formed. Consistent with an embodiment, substrate 2004 is a P-type substrate. It is understood that in other embodiments, substrate 2004 may be an N-type substrate.

FIG. 24 illustrates that a layer of oxide 2401 is grown or deposited on substrate 2004 using oxidation processes. Consistent with one embodiment, oxide layer 2401 may have a thickness in the range of 60-2000 Å. Optionally, a layer of silicon-nitride, not shown in FIG. 24, may be deposited on oxide layer 2401. Consistent with one embodiment, the silicon-nitride layer may have a thickness in the range of 500-1500 Å.

FIG. 25 illustrates the structure 2500 after masking and etching. Trenches 2501 are formed in substrate 2004. According to one embodiment, the trench depth is between 0.5 μm and 20 μm. After trenches 2501 are formed, a layer of oxide having a thickness of, e.g., 150˜500 Å, is grown over the structure 2500 (not shown in figure). This oxide is grown to remove any defects formed during the trenching process.

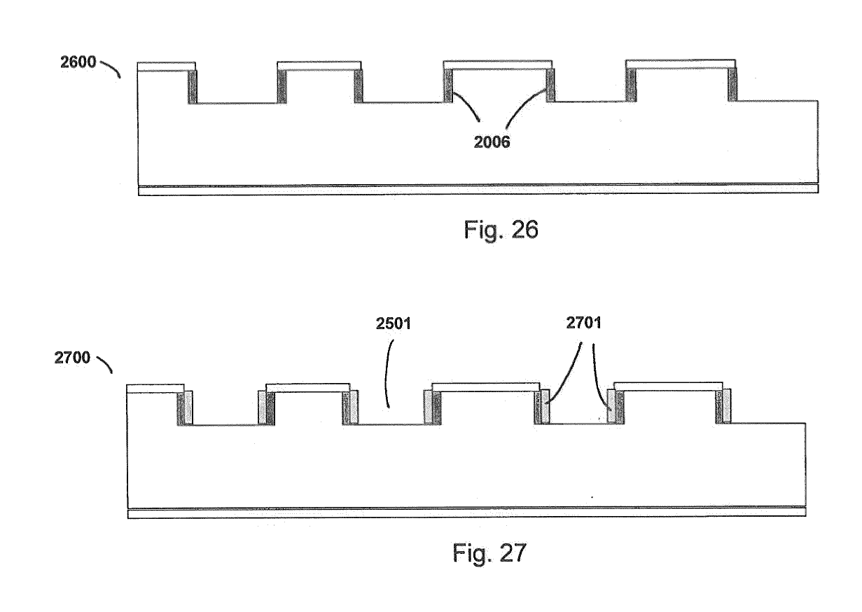

FIG. 26 illustrates the structure 2600 after forming N-type junctions 2006 on the side walls of the trenches. N-type doping may be performed by phosphorous implantation with a concentration of 2˜14×10¹³ atoms/cm². Alternatively, N-type doping may be performed by diffusing a dopant such as POCl₃. Next, a thermal anneal is performed at the temperature of, e.g., 850-1050° C. for a period of, e.g., 30 minutes. It is understood that a layer of polysilicon having a thickness in the range of, e.g., 300-3200 Å, may optionally be deposited on the structure 2600 prior to diffusion of the N-type dopant such as POCl₃.

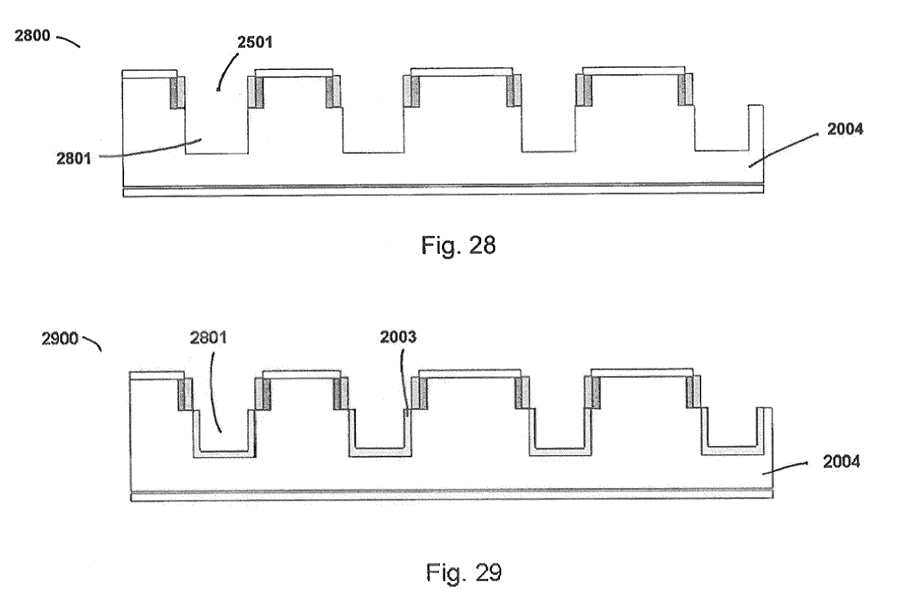

FIG. 27 illustrates the structure 2700 after using a silicon nitride or oxide or dielectric material combinations deposition and etch back processing techniques. Insulator layers 2701 are formed on the side walls of trenches 2501. FIG. 28 illustrates the structure 2800 after trench etching. Trenches 2801 are formed within trenches 2501 of substrate 2004.

FIG. 29 illustrates forming P+ regions 2003 within P-type substrate 2004, particularly in the side and base surfaces of the narrower trenches 2801. Using ion implantation, a high dose of boron atoms (4-5×10¹⁴ atoms/cm² at 40˜60 keV) may be implanted into the side and base surfaces of the narrower trenches 2801 and driven in a high temperature furnace of 900˜1000° C. for 0.5˜10 hours to diffuse the doping material. It is understood that doping may be performed by the process of diffusion using BBR₃ as the doping material.

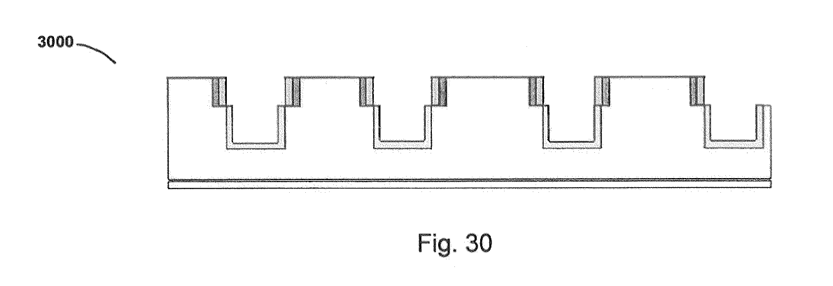

FIG. 30 illustrates structure 3000 after removing the existing oxide layers. From this point on, the process illustrated in FIGS. 12-18 and described in paragraphs [0046] to [0048] can be used to complete construction of the pillar cell structure. It is understood that some of the process can be reduced or omitted and that other process combinations are possible.

Embodiments and methods as described herein have significant advantages over prior art implementations. As will be apparent to one of ordinary skill in the art, other similar apparatus arrangements are possible within the general scope. The embodiments and methods described above are intended to be exemplary rather than limiting, and the bounds should be determined from the claims.

We claim:

1. A photovoltaic cell structure, comprising:
a semiconductor substrate;
a plurality of pillars formed from the semiconductor substrate, each one of the plurality of pillars having one or more lateral surfaces; and
a P-N junction formed underneath the one or more lateral surfaces of the plurality of pillars.

2. The photovoltaic cell structure of claim 1, wherein the pillars are formed from the semiconductor substrate by etching away portions of the semiconductor substrate.

3. The photovoltaic cell structure of claim 1, wherein at least one of the one or more lateral surfaces of at least one of the plurality of pillars is coated with a metal layer.

4. The photovoltaic cell structure of claim 1, wherein the pillars are rectangular pillars.

5. The photovoltaic cell structure of claim 1, wherein the pillars are cylindrical pillars.

6. The photovoltaic cell structure of claim 1, wherein the plurality of pillars are arranged in a staggered row pattern.

7. The photovoltaic cell structure of claim 1, wherein the plurality of pillars are arranged in a grid-like pattern.

8. The photovoltaic cell structure of claim 1, wherein the distance between adjacent pillars of the plurality of pillars is less than 4 μm.

10. The photovoltaic cell structure of claim 3, wherein the metal layer is part of a metal contact.

11. A method for fabricating a photovoltaic cell structure, comprising:
forming a plurality of pillars on a semiconductor substrate such that each one of the plurality of pillars have one or more lateral surfaces; and
creating a P-N junction underneath the one or more lateral surfaces of the plurality of pillars.

12. The method of claim 11, wherein forming a plurality of pillars on a semiconductor substrate comprises etching away a portion of the semiconductor substrate.

13. The method of claim 11 further comprising coating with a metal layer at least one of the one or more lateral surfaces of at least one of the plurality of pillars.

14. The method of claim 11, wherein forming a plurality of pillars on a semiconductor substrate comprises forming a plurality of rectangular pillars.

15. The method of claim 11, wherein forming a plurality of pillars on a semiconductor substrate comprises forming a plurality of cylindrical pillars.

16. The method of claim 11, wherein forming a plurality of pillars on a semiconductor substrate comprises forming the plurality of pillars in a staggered row pattern.

17. The method of claim 11, wherein forming a plurality of pillars on a semiconductor substrate comprises forming the plurality of pillars in a grid-like pattern.

18. A photovoltaic cell structure, comprising:
a semiconductor substrate;
one or more trenches formed on the top surface of the semiconductor substrate; and
a self-aligned P/P+ junction created within the one or more trenches.

19. The photovoltaic cell structure of claim 18 further comprising:
a plurality of pillars formed from the semiconductor substrate, each one of the plurality of pillars having one or more lateral surfaces; and
a P-N junction formed underneath the one or more lateral surfaces of the plurality of pillars.
